(19) United States
(12) Patent Application Publication
(10) Pub. No.: US 2006/0208257 A1
(43) Pub. Date: Sep. 21, 2006

(54) Method for low-temperature, hetero-epitaxial growth of thin film cSi on amorphous and multi-crystalline substrates and c-Si devices on amorphous, multi-crystalline, and crystalline substrates

(76) Inventors: Howard M. Branz, Boulder, CO (US); David S. Ginley, Evergreen, CO (US); Charles W. Teplin, Boulder, CO (US)

Correspondence Address: PAUL J WHITE, SENIOR COUNSEL;NATIONAL RENEWABLE ENERGY LABORATORY (NREL), 1617 COLE BOULEVARD, GOLDEN, CO, 80401-3393, US

(21) Appl. No.: 11/083,345

(22) Filed: Mar. 15, 2005

(51) Int. Cl. H01L 29/786; H01L 21/20

(52) U.S. Cl. 257/49; 438/478; 438/503; 257/66

(57) ABSTRACT

A crystalline, highly textured or biaxially textured, foreign (non-silicon) material, which is closely lattice-matched to silicon, is deposited on a glass or other amorphous or multi-crystalline substrate to provide a template for hetero-epitaxial growth of highly ordered crystalline silicon semiconductor layers on such substrates. This process enables crystalline silicon semiconductor devices, such as photovoltaic devices, transistors, and the like, on such inexpensive substrates, or to enable reduced temperature processing for some kinds of semiconductor devices, such as bottom gate transistors, on crystalline silicon substrates.

### CONTRACTUAL ORIGIN OF THE INVENTION

The United States Government has rights in this invention under Contract No. DE-AC36-99GO10337 between the United States Department of Energy and the National Renewable Energy Laboratory, a Division of the Midwest Research Institute.

### BACKGROUND OF THE INVENTION

1. Technical Field of the Invention

This invention is related generally to thin-film, semiconductor devices, and, more particularly, to methods for producing crystalline silicon (c-Si) films on low-cost substrates, e.g., amorphous and multi-crystalline substrates, and to crystalline silicon semiconductor device structures on such low-cost substrates.

2. State of the Prior Art

Crystalline silicon has long been used in semiconductor devices because of its high charge carrier mobilities, energy conversion efficiencies, performance stability, non-toxicity, low-cost, and ready availability. However, the low-cost benefits of crystalline silicon and its attractiveness for a wider variety of semiconductor device applications would be enhanced even further by an ability to grow thin films of crystalline silicon on inexpensive substrates. Most crystalline silicon used for semiconductor applications are slabs or wafers cut from bulk crystalline silicon ingots grown from boules of melted silicon, but there is considerable waste of material due to saw-cutting the bulk material into wafers and the residual thicknesses needed to prevent breakage during processing. Additional thin films of crystalline silicon (c-Si) can be grown epitaxially on such silicon wafers to build desired semiconductor device structures, such as photovoltaic (PV) devices, transistor devices, and others, but, for many applications, it has been more cost-effective to forego the high quality devices that result from application of wafer-based crystalline silicon semiconductors in favor of less expensive substrates and other semiconductor materials. For example, low-cost, thin-films of amorphous silicon (a-Si) mass-produced on glass substrates are more cost-effective for many photovoltaic applications than crystalline silicon, even though the energy conversion efficiencies of amorphous silicon are significantly lower than the energy conversion efficiencies of crystalline silicon. Also, while only about 20 to 30 μm of crystalline silicon is actually needed for effective light trapping in solar cells, conventional crystalline silicon solar cells use crystalline silicon wafers that are about 200 to 300 micrometers (μm) thick, because it is difficult to saw them thinner and not break them in the processing. Also, thin-film transistor arrays that drive light-emitting diodes in flat-screen displays are normally fabricated from thin-films of amorphous (a-Si), despite the lower mobility of a-Si that causes lower speed transistors, which makes such arrays inferior to transistor arrays that could be fabricated at smaller size and greater cost on Si wafers. Certain critical array-controlling transistors at the edges of flat panel displays are built on thin-film polycrystalline Si crystallized by laser heating of a-Si in order to obtain higher mobilities and higher operational speeds, however this laser crystallization process is too expensive to apply generally over the full display area.

Therefore, persons skilled in the art have long sought ways to grow thin films of crystalline silicon (c-Si) on less costly substrates, such as glass, ceramics, plastics, metals, or other inexpensive materials. The problem is that silicon does not form readily into single crystal structure when it is deposited or grown on substrates that are not themselves single silicon crystals, especially at temperatures low enough for low-cost substrate materials, such as glass, metals, and plastics to withstand without softening, melting, or leaching deleterious impurity atoms into the silicon layer. The challenge, therefore, is to induce silicon deposited in thin films on foreign (non-silicon) substrate materials to form crystal structures with desirable electronic properties approaching those of single crystals, preferably forming thin films of large area single crystals, at low temperatures.

One example attempt to solve this problem involves fabrication of large-grained (<1 μm) polycrystalline silicon (poly-Si) films on glass via epitaxial thickening of a large-grained poly-Si seed layer on the glass. See N. P. Harder et al., “Ion-Assisted Low-Temperature Silicon Epitaxy on Randomly Textured Seed Layers on Glass,” Crystal Growth & Design, Vol. 3, No. 5, pp. 767-771 (2003). In that example, a low-temperature ion-assisted deposition was used to epitaxially thicken seed layers made by aluminum-induced crystallization (ALIC) on glass substrates. While that approach has advanced the state of the art in epitaxial growth of a continuous silicon film of large crystal grains (2 μm demonstrated and said to have the capability of 20 μm or more), it has no control of seed layer crystallite orientation. The Harder et al. ALIC seed layer is comprised of crystallite grains at many orientations resulting in a thickened Si thin-film with crystallite grains at many orientations, and the film has a preponderance of high-angle grain boundaries, which are deleterious to electronic properties. For example, such high-angle grain boundaries act as trapping and recombination states for electron and hole carriers in devices, which is deleterious to charge carrier mobilities. Hydrogen passivation steps after growth can reduce the deleterious effects of these high-angle and uncontrolled grain boundaries on device performance, but electronic quality is still far inferior to single crystal wafer silicon. For example, solar cell efficiencies of such ALIC devices are about 5% instead of the 15 to 20% regularly obtained on glass.

Other efforts have been focused on developing biaxially textured, foreign (non-silicon) template layers on various substrate materials, and then growing thin films of c-Si hetero-epitaxially on the foreign template layers. For example, the U.S. Pat. No. 5,556,463, issued in 1996 to Gruenzer, illustrates a templating layer of Bi₄Ti₃O₁₂ (BTO) or other perovskite materials on several substrate materials, including silica (SiO₂), borosilicate glass, and others. The Bi₄Ti₃O₁₂ is said to be a highly crystallographically oriented along the z-axis, and its a-axis and b-axis crystallographic spacings are closely matched to silicon (Si). The Bi₄Ti₃O₁₂ template layer formed a mosaic crystalline structure, and a Si layer was then deposited on the Bi₄Ti₃O₁₂ under conditions such that the Si was epitaxial with the underlying Bi₄Ti₃O₁₂. Since the Bi₄Ti₃O₁₂ formed a mosaic crystalline structure, so did the Si layer. See Gruenzer patent, column 2. This process can be performed at low temperatures. While the resultant crystallographically oriented silicon does not have the very high quality of singly crystalline silicon, the inventor believed it would be better than polycrystalline silicon and that transistors should be able to be formed therein. See Gruenzer patent, column 2.

The Gruenzer patent extends the teachings in the Ramesh patents (U.S. Pat. Nos. 5,270,298 and 5,248,564) regarding growth of BTO on amorphous (SiO₂) substrates by hypothesis (no experimental verification) to the growth of Si on the BTO based on the lattice constant of BTO being the same as Si. The Gruenzer patent is directed to integrated circuits, and neither solar cells nor large area are mentioned or considered. The fact typical conditions for PLD Growth of BTO (the only buffer discussed in the Gruenzer patent) are for high temperature and very small sample size. There is no validation for growing Si on this buffer or that it will texture. The grain size issue is not addressed. Only one axis orientation is discussed, and there is a SiO₂ interface layer between the substrate and the BTO.

U.S. Pat. No. 6,821,338, issued to Reade et al. in 2004, also describes fabrication of biaxially oriented, crystalline templates on non-single crystal substrates, such as metal, SiO₂, silica glasses, plastics, and other non-crystalline and polycrystalline materials. A template material is deposited onto the substrate, and then the template material is processed with an oblique particle beam to give it a biaxial orientation. Then, a crystalline active layer of thin-film material or superconductor material is deposited on the biaxially oriented template, which promotes or nucleates epitaxial crystal growth of the crystalline active layer.

The Reade et al. patent lists many possible template materials, including, inter alia, CeO₂, ZrO₂, and many others, as well as a large list of possible crystalline active layer materials includes, inter alia, Si. However, those lists could be characterized as mere speculation, since there are no common characteristics provided to relate the listed orientable materials and active layer materials to those actually tried and tested. Therefore, there is no basis or teaching on which such other listed materials can actually be expected to form and function in the manner or in the structure described in Reade et al. Similarly, while the Reade et al. patent lists many known deposition processes for possible use in depositing the orientable material and the active layer material, there is no verification or justification for the inclusion of any of those processes in the list other than the pulsed laser deposition used on yttria stabilized zironia and YBCO in the first example and the plasma-enhanced chemical vapor deposition used for a-Si:H and silicon nitride in the second example.

### SUMMARY OF THE INVENTION

Accordingly, a general object of this invention is to provide a method for fabricating crystalline silicon (c-Si) active semiconductor layers on amorphous or multi-crystalline substrates.

A more specific object of this invention is to provide a method for fabricating thin-film Si with electronic quality approaching that of single-crystal wafer Si by growing large, biaxially textured grains of Si with few deleterious high-angle grain boundaries and, preferably, with large-area, inexpensive techniques on amorphous or multi-crystalline substrates at low enough temperatures to include glass, metals, plastics, and other substrate materials that lose their structural integrity at higher temperatures, for example at temperatures below about 630° C.

Another object of the invention is to provide efficient, inexpensive semiconductor devices by fabricating high quality, thin-film crystalline silicon on inexpensive amorphous or multi-crystalline substrates.

Another more specific object of the invention is to provide an efficient, inexpensive, photovoltaic device comprising one or more thin-film crystalline silicon cells on an inexpensive amorphous or multi-crystalline substrate.

Still another object of the invention is to provide an inexpensive semiconductor transistor device comprising a thin-film crystalline silicon transistor device on an inexpensive amorphous or multi-crystalline substrate.

Yet another more specific object of the invention is to provide a bottom gate thin film crystalline silicon transistor on glass or inexpensive other amorphous or multi-crystalline substrate material.

Additional objects, advantages, and novel features of the invention are set forth in part in the description that follows and will become apparent to those skilled in the art upon examination of the following description and figures or may be learned by practicing the invention. Further, the objects and the advantages of the invention may be realized and attained by means of the instrumentalities and in combinations within the scope of the claims below.

To achieve the foregoing and other objects and in accordance with the purposes of the present invention, as embodied and broadly described herein, the problem of controlling the crystal orientation of silicon films grown at low temperatures and at moderate vacuums on glass or other amorphous or multi-crystalline substrates is circumvented by depositing a template coating of a foreign (non-silicon) material with textured, preferably biaxially-textured, crystalline order on the substrate, thereby enabling subsequent epitaxial growth of crystalline silicon films. With the foreign template layer in place on the substrate, a seed layer of crystalline silicon or an entire crystalline silicon cell or other thin-film crystalline silicon structure can be grown hetero-epitaxially on the foreign template layer using a low-temperature, crystalline silicon thin-film manufacturing technique. The foreign template layer provides a transition from the glass or other amorphous or multi-crystalline substrate material to a highly ordered crystalline silicon film which is textured, preferably biaxially textured, and has few deleterious high-angle grain boundaries between any grains that may be present.

The ability to grow single-crystal thin-film c-Si on a variety of substrate materials, including glass, metal, and other amorphous, multi-crystalline, and ordered crystalline materials, enables construction of thin-film c-Si semiconductor devices, including photovoltaic cells, transistors, and others. For example, a bottom gate transistor device can be constructed by depositing an electrical insulating layer of the ordered and textured foreign crystalline material on both a metal gate electrode or a textured conducting electrode and a substrate and then fabricating a crystalline silicon active semiconductor material on the foreign crystalline layer.

### BRIEF DESCRIPTION OF THE DRAWINGS

The accompanying drawings, which are incorporated in and form a part of the specification, illustrate the preferred embodiments of the present invention, and together with the descriptions serve to explain the principles of the invention.

FIG. 1 is a diagrammatic cross-sectional view of a crystalline silicon semiconductor structure fabricated on a substrate via a foreign crystalline template layer with low-angle, benign, grain boundaries according to this invention.

FIG. 2 is a diagrammatic illustration of the off-axis sputtering arrangement used to deposit biaxially textured template layers for this invention.

FIG. 3 is a X-ray diffraction pole figure of the CeO₂ produced by the inclined angle deposition on a glass substrate, which shows the crystal orientation and biaxial texturing of the CeO₂ film.

FIG. 4 shows a cross sectional transmission electron microscopy image of a silicon layer grown hetero-epitaxially on CeO₂ showing that, while two grains are present, there is only a small difference in angle between the grain orientations.

FIG. 5 shows a high resolution cross sectional transmission electron microscopy image of the CeO₂/Si interface, demonstrating that the silicon is epitaxial with the CeO₂.

FIG. 6 is a graph showing optical reflectivity data taken on a silicon wafer, a silicon film crystallized on glass, and a silicon film crystallized on CeO₂.

FIG. 7 is a diagrammatic representation of a c-Si photovoltaic device with c-Si seed layer and c-Si active layers fabricated on a foreign template layer on a glass or other low-temperature substrate according to this invention.

FIG. 8 is a diagrammatic cross-sectional view of a bottom gate transistor device of this invention.

### DETAILED DESCRIPTION OF THE PREFERRED EMBODIMENTS

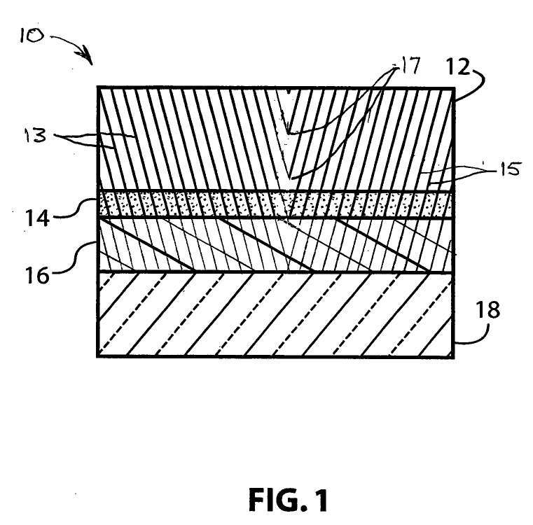

A diagrammatic representation of a photovoltaic cell structure 10, which includes a highly-ordered, thin-film, crystalline silicon (c-Si) semiconductor material 12 grown epitaxially on an amorphous or multi-crystalline substrate 18 via an intervening foreign template layer 16 according to this invention, is shown in FIG. 1. The substrate 18 can be any of a variety of either amorphous or multi-crystalline materials, including, but not limited to glass, ceramics, metals, and plastics, which cannot withstand temperatures above critical temperatures that may range from 300° C. to 630° C. The ability to grow biaxially textured c-Si on amorphous or multi-crystalline substrates in a low-temperature range of about 300° C. to 630° C. via a foreign template layer is a significant feature of this invention. The foreign template layer 16 can be comprised of any crystalline material that is closely lattice-matched to crystalline silicon and that can be grown on the amorphous or multi-crystalline substrate 18, as will be explained in more detail below. If desired, a thin-film seed layer 14 of c-Si can be grown first on the foreign template 16 as a separate step before depositing the rest of the Si cell structure 12, as will be described in more detail below, but such a separate step is not essential. The silicon cell structure 12 can be deposited as thickly as desired either directly on the foreign template layer 16 or on a c-Si seed layer 14, which can have been grown previously on the foreign template layer 16. In either approach, it is important to produce highly ordered c-Si on the template layer 16 at temperatures that the substrate can withstand on which to grow the rest of the silicon cell structure 12.

The first step of the process according to this invention is to deposit a highly ordered, preferably biaxially textured, thin-film, foreign template 16 on the amorphous or multi-crystalline substrate 18. The term “foreign” in this context means a material other than silicon. The foreign template layer 16 is preferably a material on which silicon (Si) can be grown hetero-epitaxially. Therefore, the foreign template layer 16 should be a crystalline material that is closely lattice-matched to silicon in at least one direction. The more the variation of the lattice constants, the more the strain in the growing c-Si crystalline material will tend to form dislocations and grain boundaries as the c-Si film thickens. Therefore, closely lattice-matched in this context means the lattice constant of the foreign template material should not vary from the lattice constant of silicon by more than five (5) percent. It is also preferable that the foreign template material is a good diffusion barrier to inhibit diffusion of impurities from the substrate into the silicon material 12, 14 that will be deposited on the foreign template layer 16.

One such material that meets these criteria is CeO₂, which is closely lattice-matched to silicon, and CeO₂ is a refractory material which provides an excellent diffusion barrier. The lattice constant “a” in one direction of Si is 5.431 Å and the lattice constant “a” in one direction of CeO₂ is 5.411 Å. Si has been shown to grow epitaxially on CeO₂ prior to this invention, but only at temperatures above 800° C. and by using molecular beam epitaxy (MBE). Hetero-epitaxial growth of c-Si on CeO₂ has not been demonstrated at low temperature or on thick films prior to this invention.

CeO₂ can be grown with a biaxial texture on glass and other amorphous and multi-crystalline substrate materials, which is preferred for the template layer 16 of this invention. Textured crystalline materials are materials in which a high fraction of the crystalline grains in the materials are oriented along at least one of the three orthogonal axes “a”, “b”, or “c” (i.e., c-axis textured material means that most or all of the grains have their c-axis aligned in the same direction), and biaxially texturing is where a high fraction of the crystalline grains in the materials are oriented with all three of the orthogonal axes “a”, “b”, and “c” pointing in the same directions (i.e., biaxial textured material means that most or all of the grains have their a, b, and c-axis aligned in exactly the same direction so that all c's point the same way and so do all a's and all b's).

UNIAXIAL texturing is when one axis of the material is preferentially ordered in one direction. This does not mean, for example, that all of the “a” axes point in the same direction. It just means that more of the “a” axes point in a given direction than one would find in a completely randomly oriented sample. A film that was ENTIRELY uniaxial would have all of the “a” axes pointed in a given direction, but the “b” and “c” axes would be randomly pointed in the plane perpendicular to “a”. In a BIAXIALLY textured material, more of the “a” axes point in a given direction than one would find in a completely random material AND the more “b” and “c” axes point in a given orientation than one would find in a uniaxial material with completely random “in-plane” “b” and “c” orientations. A COMPLETELY biaxial material has ALL of the “a”, “b”, and “c” axes aligned in the same direction.

The biaxial texturing of the foreign template layer 16 is preferred, because a biaxially textured template layer 16 will enable growth of a biaxially textured c-Si seed layer 14 and/or a biaxially textured c-Si thickened cell structure 12, which generally has better electrical characteristics than axially textured c-Si or untextured c-Si, e.g., high mobility of electrons and holes in the c-Si.

The goal is to produce the c-Si layers 12, 14 with as few high-angle grain boundaries as possible, because high-angle grain boundaries tend to be deleterious to the mobilities, i.e., electric characteristics, of the c-Si material. Therefore, larger grains are beneficial, since there are fewer grain boundaries in a given area. Also, where grain boundaries do occur, it is desirable for them to be low-angle, benign, grain boundaries. While biaxial texturing is not essential for low-angle, benign, grain boundaries, biaxial textured c-Si is generally very likely to have a higher percentage of low-angle, benign, grain boundaries than axial textured or untextured material.

“Benign” refers to the general property of such grain boundaries that they tend not to “interrupt” the flow of electrons or holes as much as higher angle boundaries. Therefore, the carrier (electron and hole) mobility can be high despite such grain boundaries. Thus, low-angle grain boundaries are grain boundaries that do not significantly reduce carrier mobilities compared to single crystals—not nearly as much as do high-angle grain boundaries. “Benign”grain boundaries do not reduce mobility significantly as compared to the mobility which would be achieved in grain boundary-free silicon of the same doping density (in good silicon, mobility is limited by scattering from dopant impurities). Also, benign grain boundaries tend not to have high densities of minority photogenerated carrier recombination centers that spoil a solar cell. Minority carriers are the charge carriers that light produces in photovoltaic devices and that need to be pushed through the circuit. Here the quantitative measure is whether the grain boundaries contribute significantly to recombination of photogenerated carriers—in an efficient silicon solar cell, this recombination they contribute is benign if it is less than or equal to the recombination contributed by other impurities and defects.

Therefore, benign depends on how high the quality of other aspects of the silicon is (purity, point defects, etc.) and how good a solar cell or transistor one desires to make. Basically, if one starts with silicon that has lots of high-angle grain boundaries, it is generally not possible to fix it up to be suitable for making devices. Experience tells us that low-angle grain boundaries are less deleterious than high-angle grain boundaries.

According to conventional grain boundary theory, the transition from low-angle to high-angle grain boundaries occurs at a transition angle in the range 10°-20°, but is not known exactly. On the one hand experiments of the grain boundary energy suggest a transition angle near 15°. On the other hand, one can still discern single dislocations in grain boundaries with misorientation angles near 20° by high resolution imaging. There exist neither experimental data nor theoretical concepts to determine the transition angle exactly. Recently, it was shown that planar tilt boundaries with different tilt axes (<112>, <111>, and <100>) can be moved by an external mechanical shear stress, irrespective of whether the boundary is a low-angle or a high-angle grain boundary. In these experiments it was also found that there exists a sharp transition from low-angle to high-angle boundaries which could be identified by a conspicuous step in the activation enthalpy at an angle of 13.60 for both <112>- and <111>-tilt axes, but at an angle of 8.6° for <100>-tilt axis. Therefore, for purposes of definition, the transition from low-angle to high-angle grain boundaries is in the range of 10°-20° or where a conspicuous step in the activation enthalpy can be identified, whichever is more accurate for a particular material.

Consequently, it is preferred that axial textured materials for this invention have at least eighty percent (80%) of the crystalline grains with one of their axes aligned at less than a high-angle in relation to one of the axes of other grains, and that biaxial textured materials have at least eighty percent (80%) of the crystalline grains with all three of their axes aligned at less than a high-angle in relation to the respective three axes of other grains in the material. The continuous grain lines 13, 15 in FIG. 1 extending from the foreign template layer 16 through the c-Si seed layer 14 and into the c-Si thickened material 12 represents the lattice match and consequent replication of the grains from one layer to the next. The grain boundaries 17 symbolized by the V-shaped intersection of the grain lines 13, 15 represent preferred low-angle grain boundaries.

CeO₂ is also a refractive material that can function as an excellent diffusion barrier for both the Si layers 12, 14 and the glass or other substrate material 18. Therefore, the examples and illustrations provided to describe this invention often include references to CeO₂ as the material used for the template layer 16. However, there are other suitable materials for the template layer 16, as will be explained in more detail below.

As mentioned above, biaxially textured CeO₂ can be grown on glass and other amorphous or multi-crystalline substrates. For example, CeO₂ grown on glass is reported in the following references, all of which are incorporated herein by reference:
1. M. Q. Huang, J. Geerk, S. Massing, O. Meyer, H. Reiner, and G. Linker, “Textured CeO₂ buffer layers on amorphous substrates by ion-beam-assisted deposition,” Nuclear Instruments & Methods in Physics Research, Section B: Beam Interactions with Materials and Atoms 148, 793-797 (1999).
2. S. Gnanarajan, A. Katsaros, and N. Savvides, Applied Physics Letters 70, 2816-2818 (1997).
3. J. Wang, R. Fromknecht, and G. Linker, Surface and Coatings Technology 158-159, 548-551 (2002).
4. Shen Zhu, Douglas H. Lowndes, J. D. Budai, and D. P. Norton, Appl. Phys. Lett. 65(16) 2012 (1994).

### EXAMPLE I

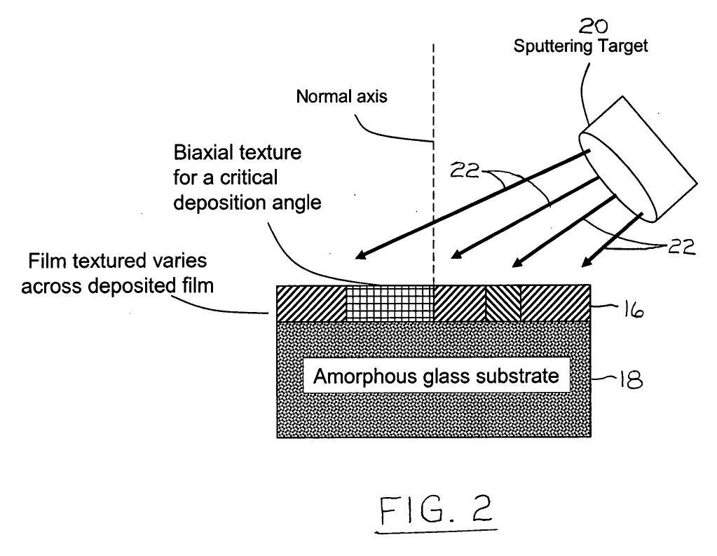

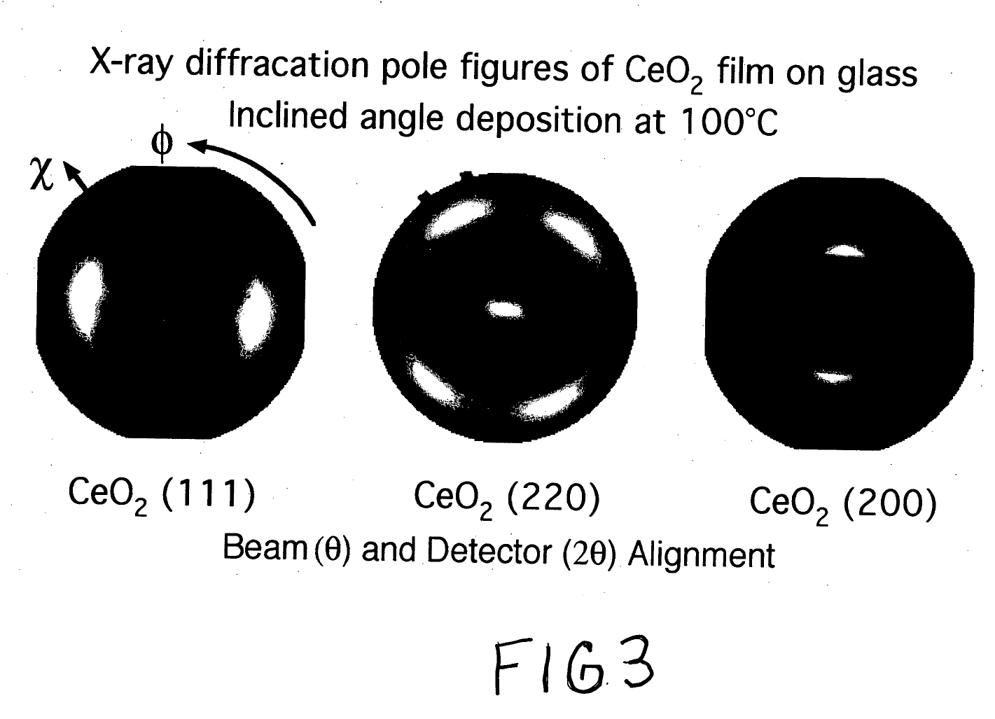

An angled magnetron-sputtering gun was used to deposit CeO₂ thin film 16 onto 2-inch by 2-inch square glass substrates, as illustrated in FIG. 2. It is found that the most of the film 16 is uniaxially textured with the preferred crystalline orientation varying as one measures parts of the film 16 near to the deposition source (sputtering target) 20 and parts of the film 16 further from the deposition source 20. The key deposition parameter is the incident angle of the depositing molecules 22. At a critical angle, it is found that the film becomes biaxially textured, as shown by the pole figure x-ray diffraction measurements in FIG. 3. The pole figure shows unequivocally that the film is biaxially textured with the (220) crystal direction normal to the substrate 18. Apparently, change of momentum of the depositing molecules 22 that results from the change of incident angle provides an extra source or cause of directionality that controls the orientation and texture of the crystallites formed in the deposited material

Example I above demonstrates two significant features of the CeO₂ deposition for use as the template layer 16. First, CeO₂ tends to deposit naturally as a textured thin film, and, second, the texturing is sensitive to the deposition environment, which can be used to control the film orientation. In the case of Example I, the depositing atoms/plasma were themselves a directional source. However, normal (perpendicular) incidence sputtering with ion bombardment (not shown), i.e., ion-beam assisted deposition (IBAD), may be a suitable alternative. Sputtering is a low-temperature deposition process, and IBAD works by forcing a controlled orientation by channeling or selective etching. Use of IBAD for forcing texturing, including biaxial texturing, is well-known in the art. See, e.g., M. Q. Huang et al., supra.

Once the textured, foreign template layer 16 is deposited, the c-Si can be grown on the template layer 16. As mentioned above, it may be preferred, but not essential, to grow a c-Si seed layer 14 first, before the thicker c-Si cell structure 12 is grown. Essentially, once a c-Si seed layer is deposited with the desired orientation and texturing, it is quite straight forward and well-known how to thicken it with more c-Si, which will continue with the orientation and texturing of the c-Si seed layer 14. For example, the thickening process to form the c-Si cell structure 12 from the c-Si seed layer 14 can be accomplished using silicon on silicon epitaxy [see, e.g., R. B. Bergmann et al., “Low-temperature Si epitaxy with high deposition rate using ion-assisted deposition,” Applied Physics Letters 72, 2996-2998 (1998)], or it can be accomplished using a amorphous silicon (a-Si) growth on the c-Si seed layer 14 followed by annealing to crystallize the amorphous silicon (see, e.g., A. G. Aberle, P. I. Widenborg, D. Song, A. Straub, M. L. Terry, T. Walsh, A. Sproul, P. Campbell, D. Inns, B. Beilby, M. Griffin, J. Weber, Y. Huang, O. Kunz, R. Gebs, F. Martin-Brune, V. Barroux, and S. R. Wenham, “Recent advances in polycrystalline silicon thin-film solar cells on glass at UNSW,” Proceedings of the 31st IEEE Photovoltaic Specialists Conference, Orlando, Fla. 2005). Both the R. B. Bergman et al., supra, and A. G. Aberle et al., supra, references are incorporated herein by reference. It is recommended that the Si be grown at chemical vapor deposition (CVD) conditions designed in a manner that persons skilled in the art would use to achieve homo-epitaxy of Si on Si substrates, even though the resulting Si structure may be undetermined in this application, and then performing solid phase epitaxy above about 500° C. to convert the Si to c-Si.

### EXAMPLE II

A sample comprising a 200 mn thick template layer 16 of biaxially textured, (100)-oriented CeO₂ grown hetero-epitaxially onto a (100)-oriented single crystal Y-stabilized ZrO₂ (YSZ) substrate using PLD was selected for growth of a c-Si seed layer 14, because it was a good quality sample of biaxially textured CeO₂ for the Si deposition experiment. The purpose of this particular experiment was to grow c-Si on biaxially textured CeO₂, not to experiment with depositing the CeO₂. The sample was cleaned by solvent dip, i.e., dipping the sample into acetone, then into isopropyl alcohol, and then into methanol, after which it was exposed to isopropyl alcohol for three minutes and then to oxygen plasma (0.5 Torr, 150 watts) for five minutes. A 60 nm film of amorphous silicon—in this case, hydrogenated amorphous silicon (a-Si:H)—by using hot-wire chemical vapor deposition (HWCVD) was grown on the cleaned CeO₂ template layer 16 under the following conditions:
Deposition time=5 minutes;
SiH₄ gas flow=20 sccm;
Ta filament current=11.5 Amps;
Substrate heater temperature=500° C.; and
Deposition pressure=10 mTorr.
Substrate to filament distance=5 cm
   The sample with the a-Si film on the CeO₂ template layer 16 was then annealed on a hot plate under flowing nitrogen gas at 560° C. for five hours to crystallize the a-Si film to form the c-Si seed layer 14. This temperature of forming the c-Si seed layer is low enough for compatibility with inexpensive glass substrates 18 on which the foreign template layer 16 will be deposited.

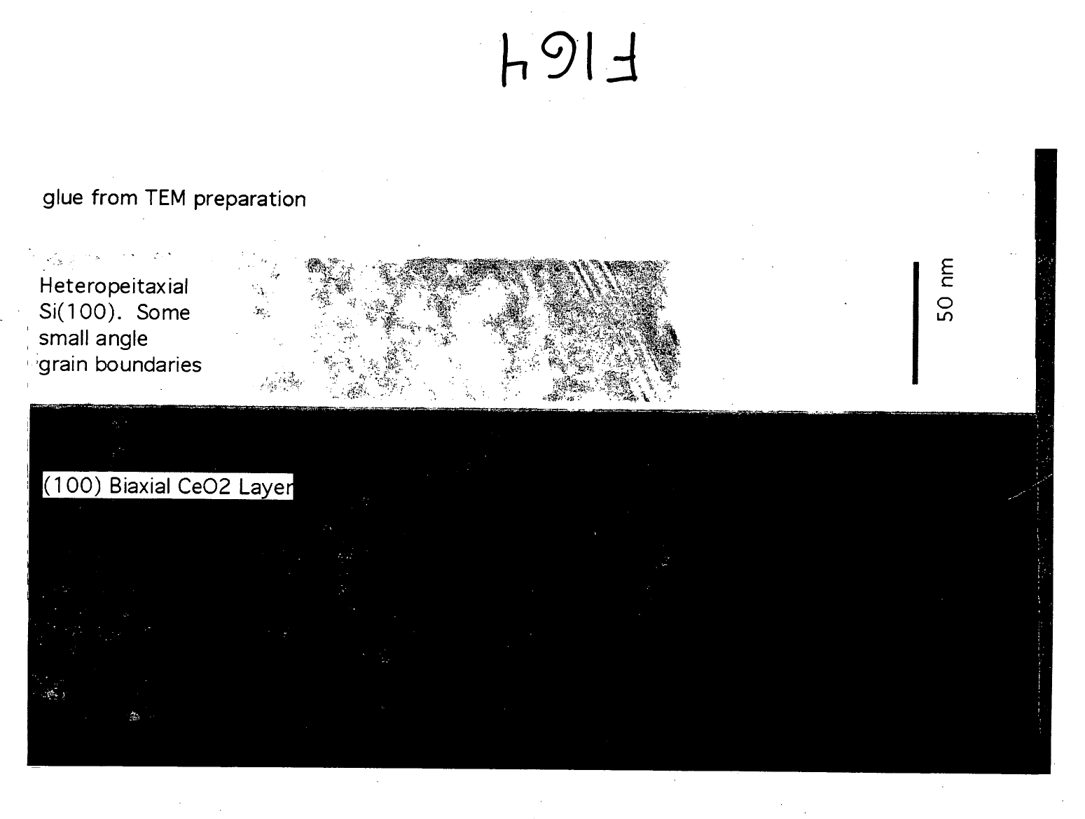

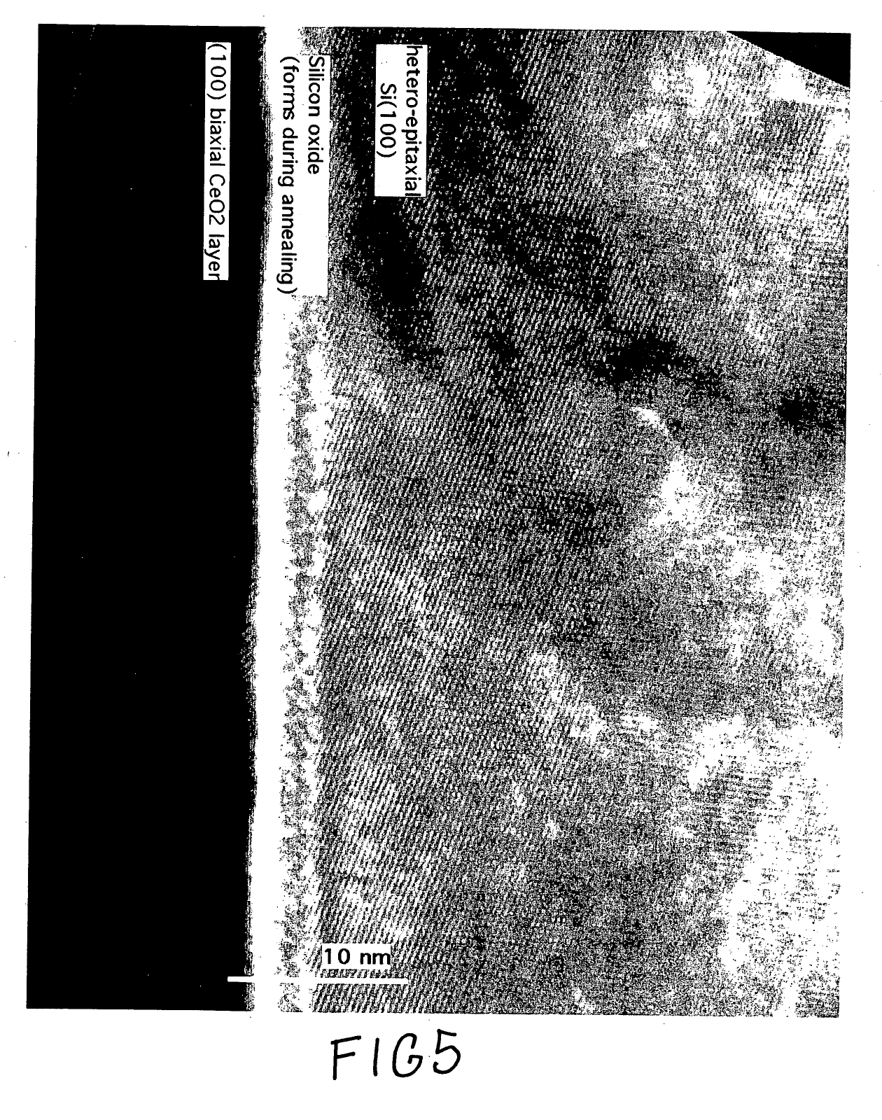

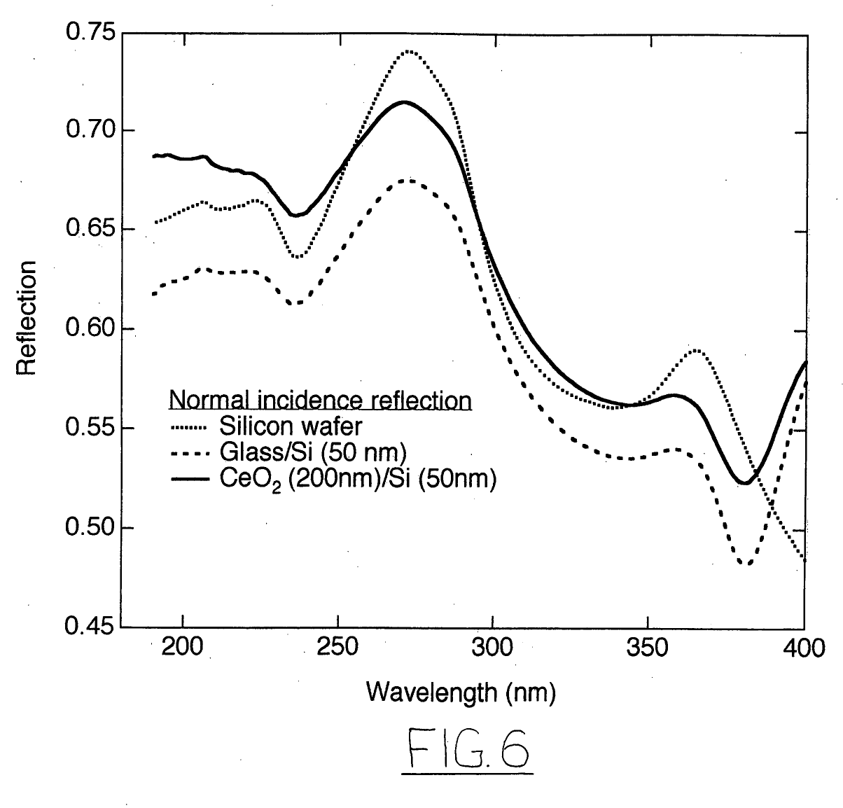

Transmission microscopy measurement of the Si/CeO₂ interface showed epitaxial growth of the Si on the CeO₂ resulting in a biaxially textured, thin film of c-Si with only low-angle and twin grain boundaries visible, as shown in FIGS. 4 (low mag TEM) and FIG. 5 (High mag TEM). In FIG. 4 (low mag TEM), the Si/CeO₂ interface is shown. There are only two grains apparent in the silicon film. Further, these grains are both (100) oriented with only a small in-plane angle between their orientations. In FIG. 5 (high mag TEM), a high resolution TEM shows that lattice plains are visible in both the CeO₂ and silicon layers, indicative of heteroepitaxy. Also visible is a thin (approximately 3-4 nm) Sio₂ layer formed the annealing, at the Si/CeO₂ interface, apparently from oxygen diffused out of the CeO₂ material, but it apparently did not inhibit the epitaxial, biaxially textured growth of the rest of the c-Si seed layer 14. Such SiO₂ at the Si/CeO₂ interface could actually provide strain relief, but that effect is only speculative. In FIG. 6, the optical reflectivity of the silicon layer is compared to a 60 nm silicon layer crystallized on glass and a silicon wafer. The large reflectivity between 270 and 370 nm indicates that the crystallized film is large-grained silicon, more similar to a silicon wafer than small-grained randomly-oriented crystal silicon that usually results when crystal silicon is grown on glass.

As mentioned above, while CeO₂ was used in the Examples described above, CeO₂ is not the only material that can be used for the foreign template layer 16. On the contrary, any crystalline material can be used that is closely lattice-matched to silicon, has material compatibility at an interface with silicon, and can be grown in an oriented and textured manner on an amorphous or multi-crystalline substrate. Material compatibility generally means stability of the interface, including thermodynamic stability of the interface with respect to reaction (at both the template substrate interface and the template/Si interface) and kinetic stability (i.e., not only can react, but also will react), as is understood by persons skilled in the art. There are a number of specific materials that are closely lattice-matched to Si and which have been demonstrated to have a compatible interface with Si by epitaxial silicon growth on such materials and/or by epitaxial growth of such materials on Si. Such materials include the following oxides, silicides, and semiconductors:
CeO₂
CoSi₂
NiSi
ZrO₂
TiN
Pr₂O₃
SiTiO₃
ZnSeₓS₁₋ₓ
GaN
BN
AlN
SiC
GaAs

For example, NiSi₂, which can be conductive, is exactly lattice-matched to Si and can be deposited by PLD and stabilized with co-doping. Si has been grown epitaxially on NiSi₂ through metal induced growth.

CoSi₂, which is lattice-matched to Si, can be deposited by PLD. Si has been grown epitaxially on CoSi₂ by molecular beam epitaxy (MBE).

ZrO₂ has a large band gap and is a robust thin-film material that blocks Na. It is an insulator that can be particularly useful in transistor applications of this invention, as will be described in more detail below. Si has been grown epitaxially on ZrO₂.

TiN is conductive and a good diffusion barrier. It is easily doped and can be deposited by PLD. TiN has been deposited epitaxially on Si.

Those examples are supported by the following articles, which are incorporated herein by reference:
1. Han, Y.-z., et al., SiOx mediated epitaxial ternary silicide (Co1-xNix)Si2. Bandaoti Xuebao, 2001. 22(10): p. 1269-1273.
2. Yew, J. Y., L. J. Chen, and K. Nakamura, Epitaxial growth of NiSi2on (111)Si inside 0.1-0.6 mm in size oxide openings prepared by electron-beam lithography. Materials Research Society Symposium Proceedings, 1996. 427(Advanced Metallization for Future ULSI): p. 547-552.
3. Richter, K. W. and K. Hiebl, NiSi1. 74A10.26 and NiSi1.83Ga0.17: two materials with perfect lattice match to Si. Applied Physics Letters, 2003. 83(3): p. 497-499.
4. Gay, J. M., et al., Epitaxial growth and lattice match of cobalt and nickel disilicides/Si(1 1 1) gold and cobalt doping of NiSi2. Physica B: Condensed Matter (Amsterdam), 1996. 221(1-4): p. 90-95.
5. Xu, Q., et al., Cobalt-self-aligned silicide method. 2002, (Micro Electronics Center, Chinese Academy of Sciences, Peop. Rep. China). Application: CNCN. p. 11 pp.
6. Ishida, K., et al., Epitaxial growth of CoSi2 on hydrogen-terminated Si(001). Applied Physics Letters, 2003. 82(12): p. 1842-1844.
7. Sakamoto, K., Epitaxial growth of thin CoSi2 film on Si(001). Purazuma Oyo to Fukugo Kino Zairyo, 1999. 8: p. 83-84.
8. Buschmann, V., et al., Hetero-epitaxial growth of CoSi2 thin films on Si(100): template effects and epitaxial orientations. Journal of Crystal Growth, 1998. 191(3): p. 430-438.
9. Bulle-Lieuwma, C.W.T., A. H. Van Ommen, and J. Homstra, Structural study of cobalt disilicide grown on (001) and (111) silicon. Institute of Physics Conference Series, 1987. 87(Microsc. Semicond. Mater., 1987): p. 541-6.
10. Kiguchi, T., et al., Role of ultrathin SiOx layer on epitaxial YSZ/SiOx/Si thin film. Integrated Ferroelectrics, 2003. 51: p. 51-61.
11. Kiguchi, T., et al., Role of ultra thin SiOx layer for epitaxial growth of YSZ/SiOx/(001)Si thin films. Journal of the Ceramic Society of Japan, 2002. 110(May): p. 338-342.
12. Ishigaki, H., et al., Effect of the thickness of SiO2 under layer on the initial stage of epitaxial growth process of yttria-stabilized zirconia (YSZ) thin film deposited on Si(001) substrate. Journal of the Ceramic Society of Japan, 2001. 109(September): p. 766-770.
13. Wang, S. J., et al., Epitaxial growth of yttria-stabilized zirconia thin film on natively oxidized silicon wafer without an amorphous layer. Semiconductor Science and Technology, 2000. 15(8): p. 836-839.
14. Bae, S.-Y., et al., Sol-gel processing for epitaxial growth of ZrO2 thin films on Si(100) wafers. Ceramics International, 2000. 26(2): p. 213-214.
15. Wakiya, N., et al., Preparation and structure of epitaxial CeO2/YSZ/Si buffer layer. Ceramic Transactions, 2000. 118(Grain Boundary Engineering in Ceramics): p. 483-490.
16. He, H., et al., Sputtering of ZnO buffer layer on Si for GaN blue light emitting materials. Science in China, Series E: Technological Sciences, 2000. 43(1): p. 55-59.
17. Nikishin, S. A., et al., High quality GaN grown on Si(111) by gas source molecular beam epitaxy with ammonia. Applied Physics Letters, 1999. 75(14): p. 2073-2075.
18. Yan, Z. J., et al., Thin HfO2 films grown on Si(100) by atomic oxygen assisted molecular beam epitaxy. Applied Physics Letters, 2004. 85(1): p. 85-87.
19. Willmott, P. R., R. Timm, and J. R. Huber, RHEED analysis of interface growth modes of TiN films on Si(001) produced by crossed beam laser ablation. Applied Surface Science, 1998. 127-129: p. 105-110.
20. Timm, R., P. R. Willmott, and J. R. Huber, Parallel epitaxy of TiN(100) thin films on Si(100) produced by pulsed reactive crossed-beam laser ablation. Applied Physics Letters, 1997. 71(14): p. 1966-1968.
21. Lee, M. B. and H. Koinuma, Structural and dielectric properties of epitaxial SrTiO3 films grown on Si(100) substrate with TiN buffer layer. Journal of Applied Physics, 1997. 81(5): p. 2358-2362.
22. Sano, K., M. Oose, and T. Kawakubo, Heteroepitaxial TiN film growth on Si(111) by low energy reactive ion bean epitaxy. Japanese Journal of Applied Physics, Part 1: Regular Papers, Short Notes & Review Papers, 1995. 34(6A): p. 3266-70.
23. Kaya, M. and Y. Atici, Studies of lattice mismatch and threading dislocations in GaAs/Si grown by MBE. Superlattices and Microstructures, 2004. 35(1-2): p. 35-44.
24. Lopatin, S., et al., Z-contrast imaging and EELS of dislocation cores at the Si/GaAs interface. Materials Research Society Symposium Proceedings, 2003. 744(Progress in Semiconductors II—Electronic and Optoelectronic Applications): p. 25-28.
25. Mendez-Garcia, V. H., et al., Control of the crystal quality of ZnSe thin films grown on GaAs and Si substrates by molecular beam epitaxy. Recent Research Developments in Vacuum Science & Technology, 2001. 3: p. 159-171.
26. Maehashi, K., et al., Molecular beam epitaxial growth and characterization of GaAs films on thin Si substrates. Japanese Journal of Applied Physics, Part 1: Regular Papers, Short Notes & Review Papers, 1998. 37(1): p. 39-44.
27. Romano, L. T., et al., Interface structure of ZnS/Si(001) and comparison with ZnSe/Si(001) and GaAs/Si(001). Physical Review B: Condensed Matter, 1995. 52(15): p. 11201-5.

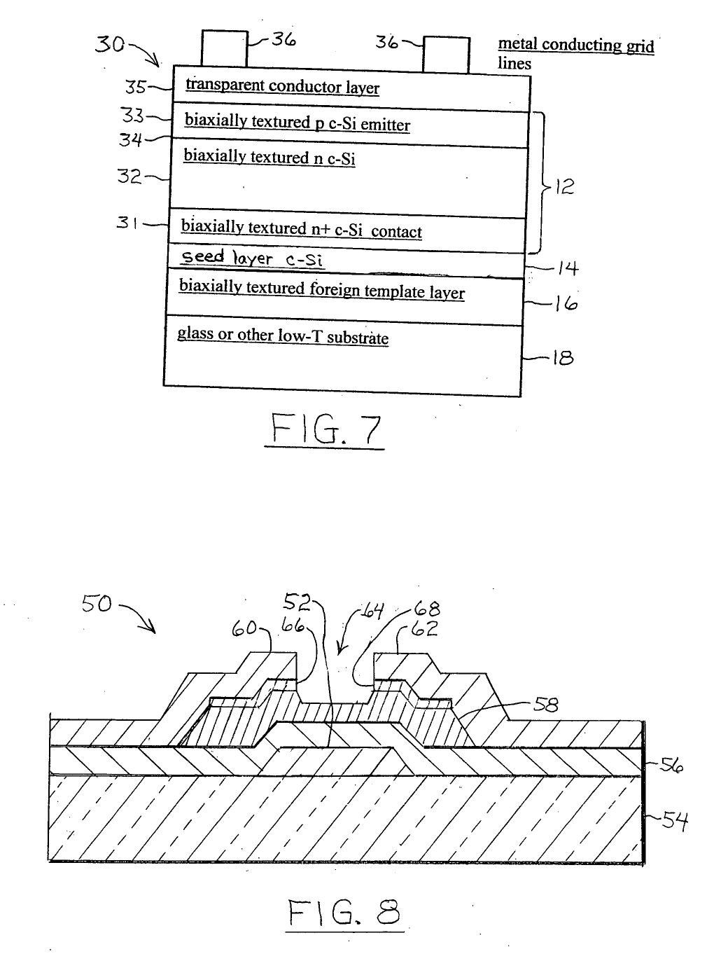

As mentioned above, a significant benefit of this invention is the ability to grow c-Si cells, such as solar cells or other photovoltaic cells, on inexpensive substrates, such as glass or other amorphous or multi-crystalline materials. An example Si solar cell 30 constructed according to this invention is shown diagrammatically in FIG. 7. The template layer 16 and c-Si seed layer 14 are grown on the glass or other low-temperature or multi-crystalline substrate 18 as described above. The c-Si thickened material 12 is doped in whatever manner is needed to fabricate the desired PV cell, as is known to persons skilled in the art. In the simple PV cell example of FIG. 7, the thickened c-Si 20 is initially doped n⁺ to form a contact layer 31, which is followed by n-doped c-Si 32 and then p-doped c-Si emitter layer 33 to form a n-p homojunction. A transparent conductor layer 35 and metal conductor grids 36 deposited on the emitter layer 33 finish the device structure. Again, the PV device structure 30 is only one simple example. Once the template layer 16 (and optionally the c-Si seed layer) 14 is in place, any kind of thin-film c-Si device structure can be fabricated.

A significant feature of this invention is the inexpensive, manufacturability of thin-film c-Si devices enabled by the ability to grow high quality, biaxially textured c-Si on inexpensive, low-temperature substrates according to this invention. Such inexpensive manufacturability depends upon several factors:

1) Use of moderate vacuum, probably above 10ˆ−7 torr. This moderate vacuum excludes molecular beam epitaxy (10ˆ−10 torr) and e-beam evaporation (10ˆ−9 torr). It also excludes ion beam techniques which also require high vacuum. For example, deposition of Si on CeO₂ at low temperatures prior to this invention, as reported by C. G. Kim, “Initial growth analysis of Si overlayers on cerium oxide layers,” J. Vac. Sci. Technol. B 18(6), p. 2650, November/December 2000, and by J. T. Jones et al., “Epitaxial silicon grown on CeO₂/Si (111) structure by molecular beam epitaxy,” J. Vac. Sci. Technol. B 16(5), p. 2686, September/October 1998, were both high vacuum techniques. The Reade ion beam approach described above also requires high vacuum. Excluding those techniques leaves low cost large area techniques such as sputtering, CVD, solution based precursors, and sol gel, which would be acceptable.

2) Speed and simplicity. If deposition is too slow, or if there are multiple steps required to form a layer, factory capital costs will become excessive. This excludes processes like atomic layer epitaxy (ALE) because of the slow rate of growth. For solar cell thicknesses, growth techniques must be above Å/s rates. For the thinner template layers, 0.1 Å/s may be acceptable. These foreign template approaches already introduce some complexity: it is important that the layers themselves go down in simple ways. The process whereby a layer is deposited and then subsequently processed by an ion beam, such as practiced by Reade, is probably prohibited by this criteria as well. Sputtering and CVD are proven fast, simple, and scalable techniques.

3) Scalability. The techniques must be capable of coating meters-squared of substrate in a reasonable time. Both solar cells and flat panel displays are essentially commodities in which large areas must be coated to realize full economies of scale in manufacturing. The need in both of those technologies for substrates from 1-3 meters in linear dimension also excludes a variety of other high-tech small area deposition approaches. Essentially, technologies that already work in the glass industry are appropriate for consideration, such as sputtering, CVD, solution based precursors, and sol gel. Molecular beam epitaxy (MBE), laser assisted expitaxial growth techniques, and other spot or focused deposition systems that work on small areas are not economical for the large areas, such as those discussed above.

4) Use of low temperatures. This allows the glass or thin metal substrates to survive depositions without flowing, deforming, or melting. It also reduces the cost because the thermal budget is less. The upper values of low temperature depend on the substrate, but is probably limited top about 600° C. for ordinary glass and about 630° C. for borosilicate glass. Clearly, the lower the temperature the better. In addition, the use of lower temperature means that interfacial problems and thermal mismatch issues will be reduced.

Valid criteria for the template layer include all of the following (though it may be possible to bypass some of these in some cases):
Lattice match—the degree of perfection of the orientation of the template and Si;
Thermal mismatch—the less the better to minimize strain and defect formation;
Conductivity—some applications need a dielectric and some a conductor;
Stability of the interface—this reflects foremost the thermodynamic stability of the interface with respect to reaction (i.e., includes both the glass and Si interfaces) but also includes the kinetic stability (i.e., it can react, but it might not);
Diffusion barrier—in some cases, the layer should prevent diffusion from the glass to the Si or vice versa;
Stress relief—the layer may act to relieve stress between the glass and Si films.

Another application of the invention is the fabrication of high mobility, thin-film c-Si transistor devices on inexpensive glass or other amorphous or multi-crystalline substrates. A particular advantage is enablement of bottom gate Si transistor structures on glass or other inexpensive substrates. Since CeO₂ and other foreign template materials, that are lattice-matched to silicon and otherwise compatible as described above, can be grown on amorphous and multi-crystalline substrate materials, including metals, such CeO₂ or other foreign template can be deposited on a metal bottom contact and substrate components of a silicon transistor device, as will be describe below.

A bottom gate transistor structure 50 according to this invention is illustrated diagrammatically in FIG. 8. A metal gate electrode 52 is deposited or otherwise placed on a substrate 54, which is preferably glass or other low-temperature, amorphous or multi-crystalline substrate for cost effectiveness. The metal bottom contact 52 can be fabricated on the substrate 54 in any desired geometric pattern by any standard method, such as sputtering, ink-jet printing or evaporation, which is well known in the art. This bottom metal contact 52 could also be deposited as a biaxially-textured film of a conducting material lattice matched to the foreign template layer 56, from among the conducting materials described above, as for example NiSi₂, CoSi₂ or TiN.

Then, a foreign template layer 56 of an electrical-insulating, crystalline material, for example CeO₂ or ZrO₂, is deposited on both the substrate 54 and the bottom contact 52 to have a biaxial texture as described above. As also described above, the crystalline template layer 56 should be highly ordered and textured, preferably biaxially textured, as well as closely lattice-matched to Si in order to provide a base for growing an active c-Si transistor layer 58 and c-Si upper contact layer 66, 68 with good electron carrier mobility, which can be accomplished with CeO₂ and other foreign template materials as explained above. Therefore, the highly ordered and textured, foreign template deposited on both the substrate 54 and the bottom metal contact 52 provides a template for growing the epitaxial c-Si active transistor layer 58 over both the substrate 54 and the bottom electrode 52.

The transistor 50 illustrated in FIG. 8 is a basic, inverse staggered, bottom-gate TFT, but any bottom-gate transistor configuration would be improved by incorporation of higher mobility crystalline Si grown on an insulating material which can be grown biaxially textured at low temperature and can serve as a foreign template for the c-Si layer. The foreign template material 56 of thickness 2 to 10 nm is deposited on the gate 52. Then a crystal Si bilayer is deposited with the first 30 to 300 nm layer 58 substantially intrinsic and a thinner 5 to 100 nm n⁺-doped layer 66, 68 on top of the intrinsic c-Si layer 58. These n+-doped layers 66, 68 form a key part of the source 60 and drain 62 and will serve to make a good ohmic contact to the source 60 and drain 62 metals. Metal source 60 and drain 62 contacts are made by metal deposition followed by etching of a groove 64 into the metal and through the n⁺-layer to isolate them from each other. With a voltage difference applied to the source 60 and drain 62, little current flows through the intrinsic c-Si layer 58. However, when a voltage is applied to the gate 52, substantial source-drain current will flow. Thus the gate-voltage can control the flow of source-drain current giving rise to transistor action as is well-known in the transistor art. All of the deposition and etching steps needed to fabricate the transistor 50 can be done at low temperatures, i.e., below 630° C. to accommodate glass or metal substrate 54 materials and at moderate vacuums as described above. Therefore, the transistor 50 is very manufacturable and inexpensive.

If the contact 52 is metal, the CeO₂ or other foreign template 56 would still need to grow biaxially textured on the metal. However, if TiN, CoSi₂ or NiSi₂ is used as the gate electrode 52, an entirely epitaxial transistor can be grown at low temperatures that will not disturb the doping in the chip very much.

The active c-Si layer 58 can be deposited hetero-epitaxially on the template layer 56 by any of the methods that are described above for the c-Si seed layer 14 or by any other deposition process that results in biaxially-textured, epitaxial thin-film c-Si on the template layer 14. Again, as discussed above, the c-Si layer 58 can be started first with a c-Si seed layer (not shown in FIG. 8) about 5 to 50 nm thick, and then the rest of the c-Si layer 58 can be grown with the desired doping to the desired thickness on the c-Si seed layer, or the entire c-Si layer 58 can be grown at once. The desired thickness of the complete c-Si active transistor layer 58 will depend on the overall design criteria for the particular transistor being fabricated, but will typically be in a range of 35 to 400 nm. The metal contacts for the source 60 and drain 62 can be fabricated on the c-Si active transistor layer 58 by any conventional process, such as sputtering, ink-jet printing or evaporation, which are well known to persons skilled in the art.

Because the CeO₂ or other foreign template material can be grown biaxially textured and lattice-matched or closely lattice-matched to Si on both the substrate 54 and the metal bottom contact 52 or the biaxially textured foreign template gate contact, as explained above, the high mobility c-Si (epitaxial or large-grained) active transistor layer 58 can be fabricated according to this invention without the need for any small area processing, such as laser recrystallization or electric-field induced crystallization. Therefore, while this bottom gate transistor structure 50 is similar in geometry to conventional bottom gate transistors, it also has a number of advantages. For example, high mobility transistors can be fabricated on inexpensive glass or other amorphous or multi-crystalline substrates according to this invention for a variety of electronic applications, such as flat-panel display back planes. High mobility refers to the desirable ability of electrons and holes to move easily in the semiconductor material, which is a characteristic of expitaxial or large-grained crystalline silicon. The bottom gate transistor 50 of this invention incorporates the foreign template as the transistor insulator layer, and since the entire Si layer 58 is crystalline, transistors can be located anywhere in it. Also, the electrical insulating character, i.e., high dielectric constant (a high k of at least 10) of the lattice-matched CeO₂, ZrO₂, and other suitable electrical insulator materials that can be used for the foreign template layer 56, the bottom gate transistor device 50 can be made very thin and miniaturized to conform to conventional transistor insulator scaling rules. Using the high-k insulator layer as a template for the c-Si layer with processes that can all be performed at glass-compatible temperatures is a great advantage.

Since these and numerous other modifications and combinations of the above-described method and embodiments will readily occur to persons skilled in the art, it is not desired to limit the invention to the exact construction and process shown and described above. Accordingly, resort may be made to all suitable modifications and equivalents that fall within the scope of the invention as defined by the claims which follow. The words “comprise,” “comprises,” “comprising,” “have,” “having,” “include,” “including,” and “includes” when used in this specification and in the following claims are intended to specify the presence of stated features or steps, but they do not preclude the presence or addition of one or more other features, steps, or groups thereof. Thin-film in the context of this invention means a film (usually less than 10 microns) that is grown or deposited by accretion onto a substrate or onto another film by any atomic, molecular, or ionic level accretion process, for example, vacuum evaporation, sputtering, chemical vapor deposition, pyrolytic decomposition, plasma-enhanced chemical vapor deposition, or any variation, improvement, or enhancement of such processes, including but not limited to those mentioned herein, such as hot-wire chemical vapor deposition, pulsed laser deposition, ion-assisted plasma deposition, etc. The words “grow”, “deposit”, and “coat” are generally synonymous and are used interchangeably herein.

The invention and several embodiments in which an exclusive property or privilege is claimed are defined as follows:

1. A method of fabricating a thin film c-Si semiconductor device comprising:
growing a foreign template layer of textured, crystalline material that is closely lattice-matched to silicon onto a substrate; and
growing epitaxial c-Si on the foreign template layer at a temperature below 800° C.

2. The method of claim 1, wherein the c-Si is biaxially textured.

3. The method of claim 1, wherein the c-Si is a single crystal.

4. The method of claim 1, including growing the foreign template material onto the substrate by ion-assisted sputtering.

5. The method of claim 4, including sputtering the foreign template material onto a surface of the substrate at an angle that is perpendicular to the surface of the substrate.

6. The method of claim 4, including sputtering the foreign template material onto a surface of the substrate at an angle that is between perpendicular and parallel.

7. The method of claim 1, including growing the foreign template material onto the substrate by ion-assisted pulsed laser deposition.

8. The method of claim 1, including growing the foreign template layer on an amorphous substrate.

9. The method of claim 8, wherein the amorphous substrate comprises glass.

10. The method of claim 8, wherein the amorphous substrate comprises metal.

11. The method of claim 1, including growing the foreign template layer on a multi-crystalline substrate.

12. The method of claim 1, including growing the foreign template layer with biaxial texturing.

13. The method of claim 1, including growing a c-Si seed layer hetero-epitaxially on the foreign template layer by hot-wire chemical vapor deposition.

14. The method of claim 1, including growing the c-Si hetero-epitaxially on the foreign template layer.

15. The method of claim 1, including growing a thin Si layer of undetermined structure at CVD conditions designed to achieve homo-epitaxy on Si substrates and then doing solid-phase epitaxy above about 500° C., but below about 630° C., to convert the Si into c-Si.

16. The method of claim 1, including growing a c-Si seed layer on the foreign template layer by depositing amorphous silicon on the foreign template layer and then annealing the amorphous silicon to produce the c-Si seed layer.

17. The method of claim 1, wherein the foreign template layer comprises CeO₂.

18. The method of claim 1, wherein the foreign template layer comprises a material selected from a group consisting of CeO₂, CoSi₂, NiSi, ZrO₂, TiN, Pr₂O₃, SiTiO₃, ZnSeₓS₁₋ₓ, GaN, BN, AlN, SiC, and GaAs.

19. A thin-film silicon semiconductor device, comprising:
a thin-film layer of textured crystalline foreign material grown on a substrate without exceeding 630° C.; and
a thin-film layer of c-Si grown on the textured crystalline foreign material without exceeding 630° C.

20. The thin-film silicon semiconductor device of claim 19, wherein the crystalline foreign material is closely lattice-matched to the c-Si.

21. The thin-film silicon semiconductor device of claim 20, wherein the crystalline foreign material is biaxially textured.

22. The thin-film semiconductor device of claim 20, wherein the crystalline foreign material comprises CeO₂.

23. The thin-film semiconductor device of claim 19, wherein the substrate is amorphous.

24. The thin-film semiconductor device of claim 19, wherein the substrate is glass.

25. The thin-film semiconductor device of claim 19, wherein the substrate is multi-crystalline.

26. The thin-film semiconductor device of claim 19, wherein the substrate is a single crystalline material.

27. A transistor device, comprising:
a first conductive electrode on a substrate;
a layer of electrically insulating, crystalline foreign material, which is textured and closely lattice-matched to silicon, grown on both the substrate and the metal electrode without exceeding 630° C.;
a layer of crystalline silicon grown on the foreign material without exceeding 630° C.; and
a second conductive electrode and a third conductive electrode deposited on the layer of crystalline silicon without exceeding 630° C.

28. The transistor device of claim 27, wherein the first electrode is a gate, the second electrode is a source, and the third electrode is a drain of the transistor device.

29. The transistor device of claim 27, wherein the crystalline foreign material is biaxially textured.

30. The transistor device of claim 27, wherein the first conductive electrode comprises metal.

31. The transistor device of claim 27, wherein the first conductive electrode comprises a conducting material selected from a group consisting of NiS₂, CoSi₂, or TiN.

32. The transistor device of claim 27, wherein the crystalline foreign material has a k value of at least 10.

33. The transistor device of claim 27, wherein the crystalline foreign material comprises CeO₂.

34. The transistor device of claim 27, wherein the crystalline foreign material is selected from a group consisting of CeO₂, CoSi₂, NiSi—, ZrO₂, TiN, Pr₂O₃, SiTiO₃, ZnSeₓS₁₋ₓ, GaN, BN, AlN, or SiC.

35. The transistor device of claim 27, wherein the substrate comprises an amorphous material.

36. The transistor device of claim 27, wherein the first electrode is a gate electrode.

37. The transistor device of claim 31, wherein the conducting material the comprises the first conductive electrode is biaxially textured.

38. The transistor device of claim 28, wherein the substrate comprises glass.

39. The transistor device of claim 27, wherein the substrate comprises a multi-crystalline material.

40. The transistor device of claim 27, wherein the substrate comprises (100)-oriented crystal material.

41. The transistor device of claim 27, wherein the substrate comprises silicon.
